(19) United States
(12) Patent Application Publication
(10) Pub. No.: US 2026/0227706 A1
(43) Pub. Date: Aug. 6, 2026

(54) METHODS AND SYSTEMS FOR DIRECTIONAL PROCESSING

(71) Applicant: TEL Manufacturing and Engineering of America, Inc., Chaska, MN (US)

(72) Inventors: Justin James Alexander, Hillsboro, OR (US); Robert William Heussner, Hillsboro, OR (US); Samuel Clark, Hillsboro, OR (US)

(21) Appl. No.: 19/181,063

(22) Filed: Apr. 16, 2025

Related U.S. Application Data
(60) Provisional application No. 63/753,138, filed on Feb. 3, 2025.

(51) Int. Cl. G03F 7/00; G03F 7/20; H01L 21/027

(52) U.S. Cl. CPC G03F 7/70466; G03F 7/2022; G03F 7/70008; G03F 7/70458; G03F 7/70525; H10P 76/2045

(57) ABSTRACT

A method is provided for processing a substrate. The method includes receiving a substrate on a substrate holder in a processing chamber. The substrate has a major surface and a mask layer disposed over the major surface, where the mask layer includes a feature. A first angle is formed between a processing beam and a normal direction of the major surface. The mask layer is exposed to the processing beam at the first angle using a first set of process parameters. A second angle is formed between the processing beam and the normal direction of the major surface, where the first angle is different from the second angle. The mask layer is exposed to the processing beam at the second angle using a second set of process parameters.

### CROSS-REFERENCE TO RELATED APPLICATIONS

This application claims the benefit of U.S. Provisional Application No. 63/753,138, filed on Feb. 3, 2025, which application is hereby incorporated herein by reference.

### TECHNICAL FIELD

The present invention relates generally to processing substrates, and, in particular embodiments, to methods and systems for directional processing.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Many of the deposition and etch steps used to form the constituent structures of semiconductor devices are performed using plasma processes. Plasma processing techniques include chemical dry etching (CDE) (e.g., plasma ashing), physical or sputter etching, reactive ion etching (RIE), plasma-enhanced CVD (PECVD), plasma-enhanced atomic layer etch (PEALE), and atomic layer deposition (PEALD).

At each successive technology node, the minimum feature sizes are shrunk to reduce cost by roughly doubling the component packing density. The demand for low cost electronics with high functionality has driven feature sizes down to a few nanometers. With lateral dimensions approaching the scale of molecules and atoms, substrate processing technology faces the challenge of fabricating very high aspect ratio structures with processes that can also meet the stringent precision, uniformity, stability, and repeatability required for IC manufacturing. Further innovations in substrate processing systems and methods may have to be made to overcome the hurdles in the path of successful semiconductor device manufacturing.

### SUMMARY

In accordance with one aspect of the present invention, a method is provided for processing a substrate. The method includes receiving the substrate on a substrate holder disposed in a processing chamber, the substrate comprising a major surface, and a mask layer disposed over the major surface, the mask layer comprising a feature. The method further includes forming a first angle between a processing beam and a normal direction of the major surface, and exposing the mask layer to the processing beam at the first angle using a first set of process parameters. Additionally, the method includes forming a second angle between the processing beam and the normal direction of the major surface, the first angle being different from the second angle, and exposing the mask layer to the processing beam at the second angle using a second set of process parameters.

In accordance with another aspect of the present invention, a method is provided for processing a substrate. The method includes providing a substrate comprising a major surface and a mask layer disposed over the major surface. The method further includes forming a first angle between a processing beam and a normal direction of the major surface, and exposing the mask layer to the processing beam at the first angle using a first set of process parameters. The method additionally includes rotating the substrate about an axis normal to the major surface, forming a second angle between the processing beam and the normal direction of the major surface, and exposing the mask layer to the processing beam at the second angle using a second set of process parameters.

In accordance with yet another aspect of the present invention, a system is provided for processing a substrate. The system includes a substrate holder disposed in a process chamber and configured to hold the substrate, the substrate comprising a major surface, and a mask layer disposed over the major surface, the mask layer comprising a feature. The system also includes a processing beam source configured to emit a processing beam onto the substrate through a processing nozzle. Additionally, the system includes a controller coupled to the processing beam source, the substrate holder, and a memory storing instructions to be executed in the controller.

The instructions, when executed, cause the controller to: form a first angle between the processing beam and a normal direction of the major surface; expose the mask layer to the processing beam at the first angle using a first set of process parameters; form a second angle between the processing beam and the normal direction of the major surface, the second angle being different from the first angle; and expose the mask layer to the processing beam at the second angle using a second set of process parameters.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate a substrate before and after directional processing, wherein FIGS. 1A and 1C are planar views and FIGS. 1B and 1D are cross-sectional views, in accordance with various embodiments;

FIGS. 2A-2D are cross-sectional views of a substrate illustrating various steps of a variable angle method for directional processing, in accordance with an embodiment;

FIGS. 3A-3D are cross-sectional views of a substrate illustrating various steps of a dynamic angle method for directional processing, in accordance with an embodiment;

FIGS. 4A-4D are cross-sectional views of a substrate illustrating various steps of a hyper dynamic angle method for directional processing, in accordance with an embodiment;

FIG. 5 is a table of process parameters and angles of etch in different methods for directional processing, in accordance with various embodiments;

FIGS. 6A-6C illustrate exemplary data of mask remaining height in different methods for directional processing, in accordance with one embodiment;

FIGS. 7A-7C are cross-sectional views of shadowing effects in different methods for directional processing, in accordance with various embodiments;

FIGS. 8A and 8B illustrate mask undercut process in different high aspect ratio feature using directional processing, in accordance with various embodiments;

FIGS. 9A and 9B illustrate planar views of a substrate after different methods of directional processing, in accordance with various embodiments;

FIG. 10 is a flowchart of a method of determining angles of etch and process parameters to modify a substrate, in accordance with an embodiment; and

FIG. 11 is a flowchart of a method of modifying a substrate, in accordance with an embodiment; and

FIG. 12 illustrates a system for directional processing a substrate, in accordance with an embodiment.

### DETAILED DESCRIPTION OF ILLUSTRATIVE EMBODIMENTS

In semiconductor manufacturing, precise dimension control of features patterned in mask layers is essential for advanced integrated circuit fabrication. As feature dimensions decrease to nanometer scale, lateral modification of feature dimensions becomes necessary to achieve critical dimensions' designed values with direct print photolithography.

Conventional directional processing methods typically employ fixed angle of etch and process parameters throughout the etching process. However, as processing progresses and the aspect ratio decreases due to mask height reduction, fixed angle method may lead to several challenges: shadowing effects preventing the processing beam from reaching feature bottoms, excessive mask height reduction compromising subsequent pattern transfer, and non-uniform feature modification affecting pattern fidelity.

In various embodiments, this disclosure presents advanced directional processing methods that dynamically adjust angles of etch and process parameters during feature modification. As feature aspect ratios decrease during directional processing, the angles of etch may be increased accordingly to reach the feature bottoms and minimize mask height reduction. This dynamic adjustment may prevent shadowing effects and enable uniform feature modification while preserving mask layer integrity for subsequent processing steps.

The methods described herein may employ a modeling-based approach to determine optimal processing conditions. The angles of etch and process parameters may be determined through simulation based on multiple factors including mask layer material properties, initial feature dimensions, target feature dimensions, and processing beam characteristics. The method may include modeling of etch profiles prior to directional processing, enabling optimization of process conditions for different feature geometries. The modeling-based approach may reduce process development time and cost by minimizing the need for iterative experimental trials.

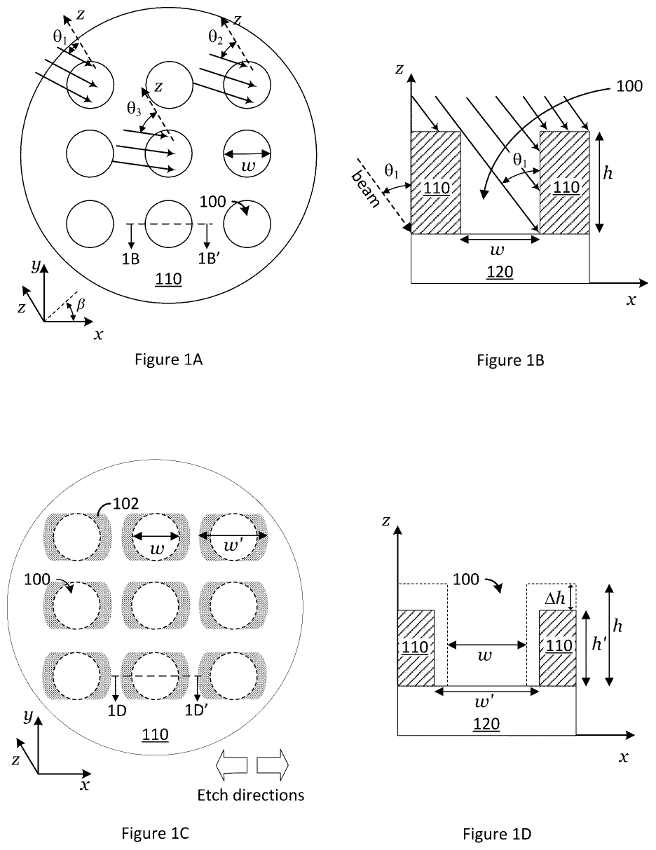

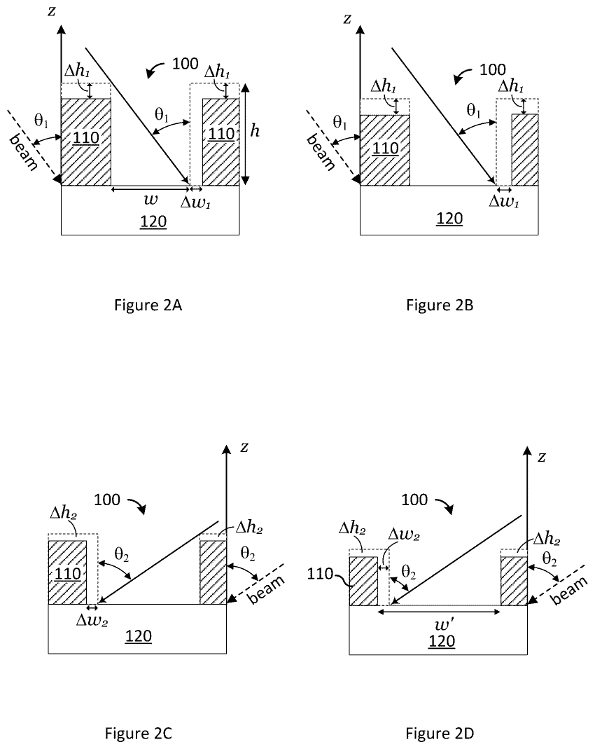

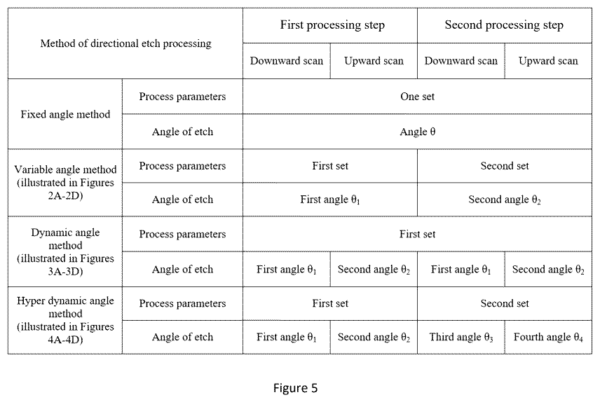

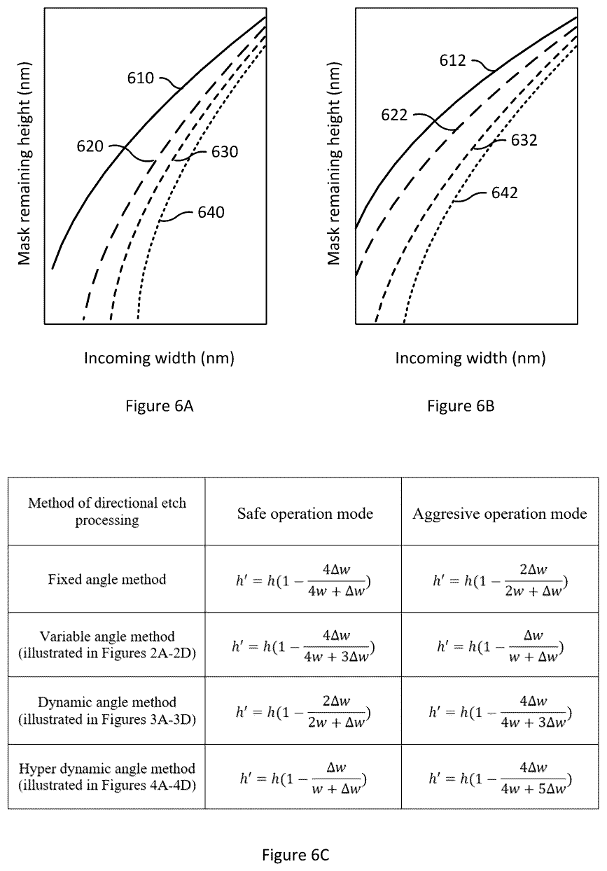

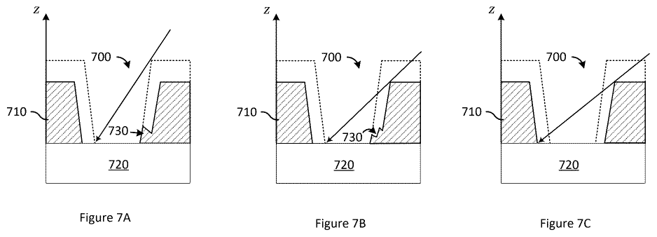

Embodiments provided below describe various methods and systems of processing a substrate, and in particular, to methods and systems that use angled beam exposure to modify a patterned mask layer before processing the substrate. The following description describes the embodiments. FIGS. 1A-1D are used to describe various stages of modifying a mask layer through illustrations of an example substrate. FIGS. 2A-2D, 3A-3D, 4A-4d are used to describe different variations in steps of modifying a mask layer. FIG. 5 is a flowchart of determining the angles of etch and process parameters involved in the process of modifying a mask layer. And FIG. 6 is a flowchart used to illustrate an embodiment method of modifying a mask layer through angled processing beam exposure. An example processing system which may implement the method of modifying a mask layer is described using FIG. 7.

FIGS. 1A-1D illustrate an exemplary modification of a mask layer over a substrate before and after a directional etch processing (e.g., a GCB processing), in accordance with an embodiment. FIG. 1A may be a planar view of the substrate before the directional etch processing, with FIG. 1B representing the corresponding cross-sectional view. FIG. 1C may be a planar view of the substrate after the directional etch processing, with FIG. 1D representing the corresponding cross-sectional view. In various embodiments, the directional etch processing may expand dimensions of features in the mask layer or smooth out dimensional variations among features in the mask layer.

In one embodiment, FIG. 1A illustrates a planar view of an array of roughly circular features 100 formed in a mask layer 110, which may be disposed over a substrate 120. The feature 100 may have an incoming width w and the mask layer 110 may have an incoming height h before directional etch processing. In some embodiments, the height of mask layer 110 may be same with the height of features 100. The cross-sectional view, corresponding to the planar view in FIG. 1A, is shown in FIG. 1B, along a cut-plane indicated by a dashed line 1B-1B′ in FIG. 1A.

The substrate 120 may comprise a bulk substrate such as a blank silicon wafer, a silicon-on-insulator (SOI) wafer, or any of various other semiconductor substrates. The substrate 120 may also be coated or layered with any number of additional materials, including compound semiconductors, metal or metal oxides, or metal nitrides. The substrate 120 may include any material portion or structure of a device, particularly a semiconductor or other electronics device.

The mask layer 110 may be a photoresist layer or a hard mask layer. In various embodiments, the mask layer 110 may be the photoresist layer comprising chemically amplified resist (CAR), metal-containing resist, metal oxide resist (MOR), or organic resist materials. In some embodiments, the mask layer 110 may be the hard mask layer comprising silicon oxide (SiO₂), silicon nitride (Si₃N₄), silicon oxynitride (SiON), silicon carbide (SiC), spin-on carbon (SOC), amorphous carbon, titanium nitride (TiN), silicon-containing organic compound, or combinations thereof.

As illustrated in FIG. 1B, the feature 100 may be formed prior to the directional etch processing. In embodiments where the mask layer 110 is a photoresist layer, the features 100 may be formed through light exposure and subsequent pattern development. In embodiments where the mask layer 110 is a hard mask layer, the features 100 may be formed by transferring patterns from an overlying photoresist layer through etching processes such as reactive ion etching (RIE), plasma etching, or wet etching.

In some embodiments, the feature 100 may be a hole extending vertically to expose a portion of a roughly planar major surface of the substrate 120. The direction of the processing beam may be represented by the arrows with an angle of etch, for example, a first angle θ₁, formed with a normal direction of the substrate 120. In various embodiments, the processing beam may be a gas cluster beam (GCB), an ion beam, an ion sheet, a plasma torch, a neutral beam stream, a particle beam, or a directional radiation from a laser. In certain embodiments, the processing beam may be the GCB comprising gas clusters of inert gases such as nitrogen and argon, or reactants such as O₂, CO₂, NH₃, NF₃, SF₆, CF₄, CHF₃, or the like, or a mixture of several gases.

The feature 100 may be modified using the processing beam which may remove materials in the mask layer 110. In some embodiments, the gas clusters in the processing beam may impact the surface of the mask layer 110, causing localized heating and chemical reactions that break chemical bonds in the mask material. The interaction between gas clusters and the mask layer 110 may result in both physical sputtering and chemical etching effects, leading to materials being evacuated out of the processing chamber.

Process parameters to control the directional etch processing may be used to control the target dimension to be modified. In various embodiments, the process parameters may comprise beam characteristics comprising beam intensity, beam energy, beam spot size, and scanning speed. In some embodiments, the process parameters may also comprise gas cluster properties such as gas composition, cluster size distribution, and gas flow rates. In some embodiments, the process parameters may further comprise exposure conditions including duration of exposing the substrate to the processing beam and dwell time at each substrate position. In another embodiment, the process parameters may further comprise environment parameters of the processing chamber such as chamber pressure, substrate temperature, and substrate bias voltage. In various embodiments, the process parameters may be adjusted individually or in combination to achieve desired etch profiles and rates while maintaining controlled feature modification.

Referring back to FIG. 1A, the x and y axes may represent reference directions in the plane of the substrate 120 and the z-axis may represent the normal to the surface of the substrate 120, also referred to as the major surface. The dimensions of feature 100 (e.g., the width w) may be defined and measured in the x-y plane. An aspect ratio of feature 100 may be defined by the height of the feature 100 divided by the width w of the feature 100, where the height of the feature 100 may be the height h of mask layer 110. In some embodiments, the origin of the x-y-z rectangular system may be selected to be at the center of the major surface. In some embodiments, a substrate holder on which the substrate is loaded may be in a plane parallel to the major surface of the substrate separated by the wafer thickness.

In various embodiments, the direction of the processing beam may remain fixed while the substrate 120 may be moved, rotated or tilted. The tilt of the substrate 120 may lead to the angle of etch formation between the direction of processing beam and the normal of major surface (or z-axis). The rotation of the substrate 120 about the z-axis may be quantified by a rotation angle θ in the x-y plane. In an embodiment, the processing beam may etch one side of the mask layer, and by rotating the substrate 120 by 180° (or β=180°), the processing beam may etch the opposite side of the mask layer.

In various embodiments, the features 100 at different positions on the mask layer 110 may be processed using different angles of etch during substrate movement. For example, one feature 100 near an edge of the mask layer 110 may be processed at the first angle θ₁, while another feature 100 near another edge of the mask layer 110 may be processed at a second angle θ₂, and another feature 100 near center of the mask layer 110 may be processed at a third angle θ₃, where the first, the second, and the third angles θ₁, θ₂, and θ₃ may be different from each other. By varying the angles, the rate of etch at different positions of the mask layer 110 may be differently controlled. The variation in angles may improve uniformity of feature dimension distribution across the mask layer 110 by compensating for potential initial dimensional variations.

In an embodiment illustrated in FIG. 1B, the substrate 120 may be tilted relative to the direction of processing beam, resulting in the normal to the major surface (z-axis indicated by the solid arrow) and the processing beam to form the first angle θ₁. The processing beam may strike one side and top surface of the mask layer 110 and start removing material from these surfaces, thereby displacing the edge of the etched sidewall along a direction in the x-y plane, also referred to as etch direction. As explained further below, the substrate may be rotated about the x-axis, y-axis, or z-axis to adjust the angle of etch.

In various embodiments, the angle of etch formed between the processing beam and the z-axis may have a minimum angle of 5° and a maximum angle of 85° (in either positive or negative directions).

FIG. 1C illustrates the edited feature 100 after the directional etch processing, in accordance with one embodiment. Regions to be etched by the processing beam may be represented by shaded regions 102. During the directional etch processing, the processing beam may etch one side of the mask layer, and by rotating the substrate 120 by 180° (or β=180°), the processing beam may etch the opposite side of the mask layer. The width of the feature 100 may be increased from w to w′ along the etch directions (e.g., along x-axis), wherein w′ may represent the target width of the feature 100 after processing. FIG. 1D shows the corresponding cross-sectional view (along a cut-plane indicated by a dashed line 1D-1D′ in FIG. 1C) of the substrate after being exposed to the processing beam. In some embodiments, the height of the mask layer 110 may be reduced to h′ (a remaining mask height) by an amount Δh. Loss of mask layer height may limit its usefulness as an etch mask in a subsequent etch step to transfer the pattern from the mask layer 110 to an underlying layer. As described in more detail below, the various embodiments in this disclosure include applying variable angles of etch and process parameters during processing to modify the width of the feature while minimizing the loss of mask layer height. In some embodiments, an increased angle of etch may be applied during the directional etch process to retain the initial height h of the mask layer 110.

While FIGS. 1A-1D illustrate the feature 100 having roughly circular shapes and holes, in various embodiments, the feature 100 may comprise various geometrical shapes and structures. The feature 100 may include, but are not limited to, rectangular shapes such as lines, square shapes, oval shapes, polygonal shapes, or irregular shapes. In one or more embodiments, the feature 100 may represent different semiconductor structures such as vias, trenches, contact holes, gate structures, fin structures, line patterns, spaces between lines, or combinations thereof. In various embodiments, the dimensions of feature 100 may include critical dimensions such as via diameter, trench width, line width, pitch, or spacing between adjacent features. In various embodiments, the processing methods described herein may be applied to modify dimensions of any of these feature types while maintaining desired aspect ratios and structural integrity. In some embodiments, different types of features 100 present on the same substrate 120 may be processed using different combinations of angles of etch, rotation angles β, and process parameters to achieve optimal dimensional control for each feature type.

FIGS. 2A-2D illustrate cross-sectional views of the substrate 120 during various processing steps of modifying the mask layer 110 using the processing beam, in accordance with an embodiment. FIGS. 2A-2D may represent a variable angle method of directional etch processing as shown in FIG. 5, where the angle of etch may change after rotating the substrate as will be described in more detail below. The mask layer 110 with an initial height h may comprise the feature 100 with an initial width w. The z-axis may represent the normal direction of the major surface of the substrate 120. The dotted regions may indicate portions of the mask layer 110 that may be removed during processing.

FIG. 2A illustrates a first processing step where the processing beam may be directed at a first angle θ₁ relative to the z-axis during a first downward scan. In an embodiment complete scan cycle, each region of the substrate may be scanned twice, where the scan direction may be downward and then upward. In various embodiments, a downward scan may refer to relative movement between the processing beam and the substrate, where a beam spot on the substrate may move from one edge of the substrate toward an opposite edge, e.g., from top of the substrate to the bottom of the substrate. Subsequently, in an upward scan, the beam spot moves in an opposite direction to the downward scan as the beam spot is moved from the opposite edge to the starting point, e.g., from the bottom of the substrate to the top of the substrate.

The first angle θ₁ may be small enough that the processing beam reaches the bottom of the feature 100. In some embodiments, the first angle θ₁ may be calculated following the equation to estimate angle of etch:

$$θ = arctan \frac{1}{AR} \qquad ( Equation 1 )$$

where θ is the angle of etch, and AR may represent the aspect ratio of the feature which is calculated as h/w. The interaction between the processing beam and the mask layer 110 may result in removal of material from the mask layer 110. As a result, the height of the mask layer 110 may be reduced by Δh₁, and the width of the feature 100 may be reduced by Δw₁.

The processing beam in FIG. 2A, in various embodiments, may be a gas cluster beam (GCB) comprising gas clusters as described reference to FIG. 1A. In alternative embodiments, the processing beam may be an ion beam, an ion sheet, a plasma torch, a neutral beam stream, a particle beam, or a directional radiation from a laser. In various embodiments, the etch process with the processing beam directed at the first angle θ₁ may use a first set of process parameters comprising an intensity of the processing beam, a duration of exposing the mask layer to the processing beam, or a composition of the processing beam.

FIG. 2B shows a subsequent upward scan, maintaining at the same first angle θ₁, where the beam spot may move in an opposite direction with respective to the downward scan. In some embodiments, the processing beam in this step may comprise the same first set of process parameters as the prior step described in FIG. 2A. While in some embodiments, one or more parameters in the second set of process parameters may be different from those in the first set of process parameters. Additional mask material may be removed during the upward scan, as indicated by the dotted regions, further modifying the height of the mask layer 110 by Δh₁ and the width of the feature 100 by Δw₁. The sequential down and up scans at the first angle θ₁ may provide improved uniform processing of the exposed surfaces of the mask layer 110.

FIG. 2C illustrates a second processing step where the substrate 120 may be rotated 180 degrees (or β=) 180° about an axis normal to its major surface, and the processing beam may be directed at a second angle θ₂, which may be larger than the first angle θ₁ to accommodate the reduction of aspect ratio of the feature 100 after processing following FIGS. 2A-2B. The second angle θ₂ may be increased based on a reduced aspect ratio to ensure processing beam reaching bottom of the feature 100 while reducing loss mask layer height. In contrast, traditional fixed angle method does not change the angle of etch through the directional etch processing, resulting in excessive mask height reduction to achieve target feature dimensions. In the variable angle method, the angle of the etch is increased to account for the loss of the mask layer height so that the entire surface of the mask sidewall is subjected to the beam spot. In addition, the increase of the angle of the etch reduces the vertical etch rate of the mask layer thereby decelerating the etching of the mask layer height. In some embodiments, the second angle θ₂ may be selected following Equation 1.

In various embodiments, the etch process at the second angle θ₂ may use a second set of process parameters. In some embodiments, the second set of process parameters may be different from the first set of process parameters in the intensity of the processing beam, the duration of exposing the mask layer to the processing beam, or the composition of the processing beam. The processing beam may follow downward scan across the substrate to etch the mask layer 110, resulting in reduced Δh₂ in the height of the mask layer 110 and Δw₂ in the width of the feature 100, where Δh₂ may be different from Δh₁. The rotation may enable processing of previously shadowed regions of the mask layer 110.

In various embodiments, while a 180° rotation illustrated in FIG. 2C may enable processing of opposite sides of the features 100, the substrate 120 may be rotated about the axis normal to the major surface by other angles to process different portions of the features 100. The rotation angle β may be determined based on feature geometry, desired etch profile, and symmetry requirements. For example, the substrate 120 may be rotated by 90 degrees, 120 degrees, or other angles to achieve uniform processing around circular features or to modify specific sidewall portions of complex geometries. Multiple rotations at different angles may be performed during processing to achieve desired feature modifications. The combination of various rotation angles β with different angles of etch may provide enhanced flexibility in controlling the etch profile and feature dimensions.

FIG. 2D illustrates a subsequent upward scan at the second angle θ₂ following the step in FIG. 2C. Additional mask material may be removed as shown by the dotted regions, with dimensional changes denoted as Δh₂ and Δw₂. The process parameters used during processing at the second angle θ₂ may be same or different from those used during the step in FIG. 2C. The etch process may continue until the target width w′ of the feature 100 is achieved.

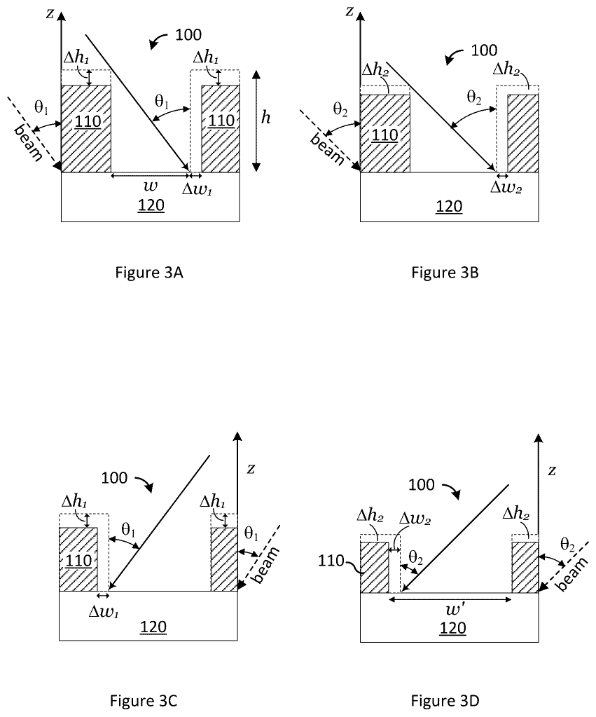

FIGS. 3A-3D illustrate cross-sectional views of an alternative processing sequence for modifying the mask layer 110 on the substrate 120, in accordance with an embodiment. FIGS. 3A-3D may represent a dynamic angle method of directional etch processing as shown in FIG. 5, where the angle of etch may change after a first downward scan as will be described in more detail below. Similar to FIGS. 2A-2D, the mask layer 110 may have the initial height h, and the z-axis may represent the normal direction of the major surface of the substrate 120. The dotted regions may indicate portions of the mask layer 110 that may be removed during processing.

FIG. 3A illustrates a first processing step where the processing beam may be directed at the first angle θ₁ relative to the z-axis during a first downward scan. In some embodiments, the first angle θ₁ may be determined following the method as described with reference to determining the first angle θ₁ in FIG. 2A. During this step, the height of the mask layer 110 may be reduced by Δh₁, and the width of the feature 100 may be reduced by Δw₁. The processing beam, in various embodiments, may be the GCB comprising the gas clusters as described with reference to FIG. 1A. In various alternative embodiments, the processing beam may be an ion beam, an ion sheet, a plasma torch, a neutral beam stream, a particle beam, or a directional radiation from a laser. In various embodiments, the processing at the first angle θ₁ may be using the first set of process parameters described above.

FIG. 3B shows a subsequent processing with the processing beam directed at the second angle θ₂, which may be adjusted based on the reduced aspect ratio of the feature 100. In some embodiments, the second angle θ₂ may be larger than the first angle θ₁ to accommodate the reduced aspect ratio. In some embodiments, the second angle θ₂ may be determined following the method as described with reference to determining the second angle θ₂ in FIG. 2C. The processing beam may follow an upward scan, further etching the mask layer 110 to reduce its height by Δh₂ and modifying the feature width by Δw₂. In various embodiments, the processing beam at the second angle θ₂ may comprise a second set of process parameters, which may be different from the first set of process parameters used in FIG. 3A. The dynamic angle method by adjusting the angle of etch and process parameters when switching from downward scan to upward scan provides improved control over feature modification by suppressing the mask loss. This method helps overcome the limitation of traditional fixed angle method in achieving target feature dimensions with excessive mask height reduction.

FIG. 3C illustrates a second processing step where the substrate 120 may be rotated by, for example, 180 degrees, about the axis normal to the major surface. The rotation may enable processing of previously shadowed regions of the mask layer 110. The processing beam may follow downward scan across the substrate to etch the mask layer 110 at the first angle θ₁, resulting in further reduced Δh₁ in the height of the mask layer 110 and Δw₁ in the width of the feature 100. In various embodiments, the process parameters in this step may be same or different with the first set of process parameters.

FIG. 3D illustrates a subsequent upward scan at the second angle θ₂ following the processing illustrated in FIG. 3C. In various embodiments, the process parameters in this scan may be same or different with the first set of process parameters. Additional mask material may be removed as shown by the dotted regions with dimensional changes denoted as Δh₂ and Δw₂. The processing may continue until the target width w′ of the feature 100 is achieved.

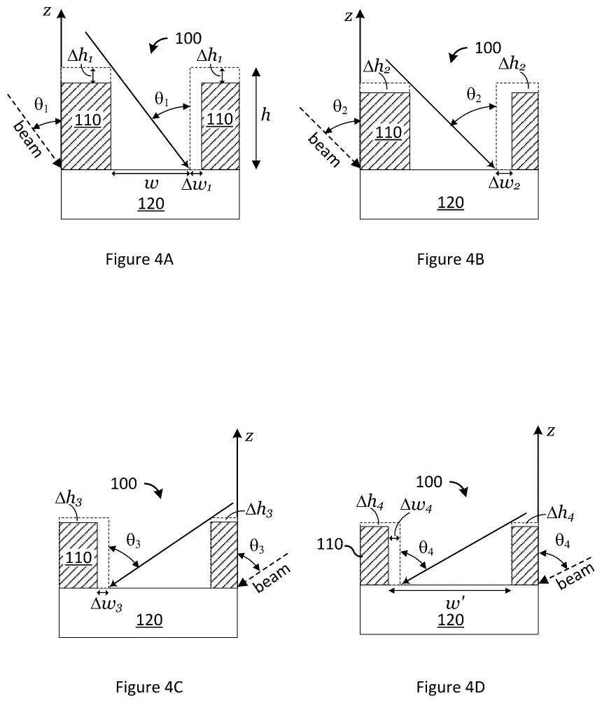

In accordance with an embodiment, FIGS. 4A-4D illustrate cross-sectional views of yet another processing sequence for modifying the mask layer 110 on the substrate 120. FIGS. 4A-4D may represent a hyper dynamic angle method of directional etch processing as shown in FIG. 5, where the angles of etch may be continuously adjusted based on aspect ratio changes of the feature 100 during processing. As etching progresses and the mask height reduces, the angles may be increased accordingly. In various embodiments, the angles of etch may be increased with the aspect ratio of the feature 100 being reduced. In various embodiments, the angles of etch may be predetermined based on modeling the etch rate of the mask layer 110 relative to the substrate 120.

FIG. 4A may illustrate a first processing step at the first angle θ₁ relative to the z-axis, where the first angle θ₁ may be selected based on an initial aspect ratio of the feature 100. The first angle θ₁ may be selected to be small enough, ensuring the processing beam reaches the bottom of the feature 100, while large enough to reduce the loss of mask layer height h. In some embodiments, the first angle θ₁ may be selected based on Equation 1. The processing may be the downward scan that reduces the height of the mask layer 110 by Δh₁ and the width of the feature 100 by Δw₁ using the first set of process parameters.

FIG. 4B illustrates continued upward scan processing at the second angle θ₂, which may be larger than the first angle θ₁ to accommodate the reduced aspect ratio of the feature 100. As mask layer material is removed and the mask height reduces, the aspect ratio of feature 100 may decrease. In some embodiments, the second angle θ₂ may be selected following Equation 1. The dotted regions may indicate additional mask material removed through the upward scan during this step, featuring a reduction in the height by Δh₂ and width by Δw₂. The processing at the second angle θ₂ may use the second set of process parameters.

FIG. 4C illustrates a second processing step where the substrate 120 may be rotated by the rotation angle β about the axis normal to the major surface. In some embodiments, the rotation angle β may be 180°. The rotation may enable processing of previously shadowed regions of the mask layer 110. The processing beam may follow downward scan across the substrate to etch the mask layer 110 at a third angle θ₃, resulting in further reduced Δh₃ in the height of the mask layer 110 and Δw₃ in the width of the feature 100. In various embodiments, the third angle θ₃ may be larger than the second angle θ₂ to accommodate the reduced aspect ratio of the feature 100. In some embodiments, the third angle θ₃ may be selected following Equation 1. In some embodiments, the processing at the third angle θ₃ may use a third set of process parameters. In various embodiments, one or more parameters in the third set of process parameters may be different from those in the second set of process parameters.

FIG. 4D shows the subsequent upward scan by the processing beam at a fourth angle θ₄, where the aspect ratio of the feature 100 has further decreased. In various embodiments, the fourth angle θ₄ may be larger than the third angle θ₃, enabling more effective processing of the feature sidewalls while suppressing the loss of mask layer height. In some embodiments, the fourth angle θ₄ may be selected following Equation 1. In various embodiments, the processing at the fourth angle θ₄ may use a fourth set of process parameters. In various embodiments, one or more parameters in the fourth set of process parameters may be different from those in the first, second, and third sets of process parameters. Additional material may be removed as shown by the dotted regions, resulting in further reduced Δh₄ in the height of the mask layer 110 and Δw₄ in the width of the feature 100. The processing may continue until the target width w′ of the feature 100 is achieved while maintaining sufficient mask layer height for subsequent processing steps.

The hyper dynamic angle method illustrated in FIGS. 4A-4D may enable dynamic adjustment of angles of etch and process parameters during each step of feature modification to accommodate changes in the aspect ratio of the features 100. As the aspect ratio decreases during processing, the angles and process parameters may be adjusted accordingly between downward and upward scans and between substrate rotation. For example, in some embodiments, the angle of etch, and the rotation of the substrate relative to the beam direction may be simultaneously changed along with the scan direction, i.e., upward scan (“up”) or downward scan “down.” For example, the scan may follow ((45, 0, down), (46, 0, up), (47, 90, down), (48, 90, up), (49, 180, down), (50, 180, up), (51, 270, down), (52, 270, up)), where each coordinate represents one beam exposure. In the first exposure, the substrate is exposed to 45 degree angle of etch, 0 degree rotation, and a downward scan. The eight scans together can give 4-fold symmetric via, for example.

This approach may provide enhanced control over feature modification while minimizing mask layer height reduction. Compared to traditional fixed angle methods, this dynamic adjustment capability may enable achievement of target feature dimensions with improved mask layer retention.

In various embodiments, the processing steps illustrated in FIGS. 2A-2D, FIGS. 3A-3D, FIGS. 4A-4D may be repeated in their entirety until target feature dimensions, for example, the target width w′ of the feature 100, are achieved. Alternatively, any individual step or combination of steps may be repeated as needed. For example, processing steps illustrated in FIGS. 4A and 4B may be repeated multiple times before rotating the substrate to process at the steps illustrated in FIGS. 4C and 4D. In some embodiments, the process parameters and angles may be adjusted between repeated steps based on intermediate measurements or monitoring of feature dimensions, for example, the width of the feature 100 and the height of the mask layer 110. This flexible approach may enable precise control over final feature dimensions while minimizing mask layer height reduction.

In various embodiments, the substrate may undergo a stabilization period between processing steps. For example, when transitioning from downward scan to upward scan, or between different angles of etch, the substrate motion may pause to allow mechanical stabilization. During this stabilization period, the processing beam may be temporarily interrupted. The duration of the stabilization period may be determined based on factors including substrate material properties, feature dimensions, and process parameters. In some embodiments, the substrate holder may maintain position while environmental conditions such as pressure of the etch chamber, temperature, or gas flow stabilize. This stabilization step may help ensure uniform processing conditions between processing steps and improve repeatability of feature modifications.

In various embodiments, between exposing the mask layer 110 to the processing beam at the different angles (e.g., the first, the second, the third, and the fourth angles θ₁, θ₂, θ₃, and θ₄), the substrate may be rotated about the axis normal to the major surface.

FIGS. 6A and 6B illustrate quantitative comparisons of mask height retention versus incoming feature width for different processing methods, demonstrating advantages of methods described in FIGS. 2A-2D, FIGS. 3A-3D, FIGS. 4A-4D. FIG. 6A illustrates a safe operation mode where the directional etch processing may utilize conservative processing parameters and angles of etch to accommodate wider critical dimension distributions typically encountered in high numerical aperture (High-NA) EUV patterning. FIG. 6B shows an aggressive operation mode where the processing parameters and angles may be optimized for tighter critical dimension distributions. The curves 640, 630, 620, and 610 in FIG. 6A (and corresponding curves 642, 632, 622, and 612 in FIG. 6B) represent remaining mask height for fixed angle, variable angle, dynamic angle, and hyper dynamic angle methods respectively.

As illustrated in both FIGS. 6A and 6B, the fixed angle method (curves 640, 642) may result in the lowest mask retention across all incoming feature widths. In contrast, the variable angle method (curves 630, 632) may show improved mask retention by implementing different angles between the first and the second processing steps. The dynamic angle method (curves 620, 622) may demonstrate further enhancement in mask height retention through optimization of angles between downward and upward scans. The hyper dynamic angle method (curves 610, 612) may achieve the highest mask retention among all approaches by enabling comprehensive angle and parameter control throughout the processing sequence.

FIG. 6C presents analytical expressions for remaining mask height (h′) as a function of incoming mask height (h), incoming feature width (w), and total feature width change (Δw) for each method in FIGS. 6A and 6B. The expressions indicate that more sophisticated angle control strategies may reduce the mask height consumption required to achieve target feature dimensions. For example, in safe operation mode, the mask height reduction term may decrease from

$$\frac{4 Δ w}{4 w + Δ w}$$

for the fixed angle method to

$$\frac{Δ w}{w + Δ w}$$

for the hyper dynamic angle method. These improvements in mask retention may be particularly beneficial for High-NA EUV applications in maintaining sufficient mask height while achieving target critical dimensions.

FIGS. 7A-7C illustrate cross-sectional views demonstrating different shadowing from different directional etch processing methods, in accordance with various embodiments. A mask layer 710 comprising a feature 700 may be disposed over a substrate 720. The mask layer 710 and the substrate 720 may comprise the structures and materials of the mask layer 110 and the substrate 120 as described in FIGS. 1A-1B. Dashed line indicates the region of the mask layer 710 before etch processing. The arrows may represent the processing beam used to etch the mask layer 710.

FIG. 7A may illustrate the fixed angle method using a single angle of etch (e.g.,) 45° during the directional etch processing in a conventional processing method. A region 730 may represent a shadowed area where the processing beam may be blocked by the opposing sidewall, resulting in incomplete or non-uniform etch processing. The shadowing effect may lead to asymmetric feature modification and reduced process control.

FIG. 7B may demonstrate the dynamic angle method as illustrated in FIGS. 3A-3D, where the processing angle may be adjusted during processing (e.g., a first angle of 41°, and a second angle of) 48°. With optimized angle of etch during etch processing, this method may reduce shadowing effects as illustrated by the reduced region 730. The ability to adjust angles during processing may enable more uniform feature modification compared to fixed angle method.

FIG. 7C may illustrate the hyper dynamic angle method as illustrated in FIGS. 4A-4D, where multiple angle of etch adjustments may be implemented during processing. In certain embodiments, the angles of etch may increase at each step (e.g., a first angle of 37°, a second angle of 41°, a third angle of 48°, and a fourth angle of 51°), enabling precise control over feature modification while minimizing or avoiding shadowing effects.

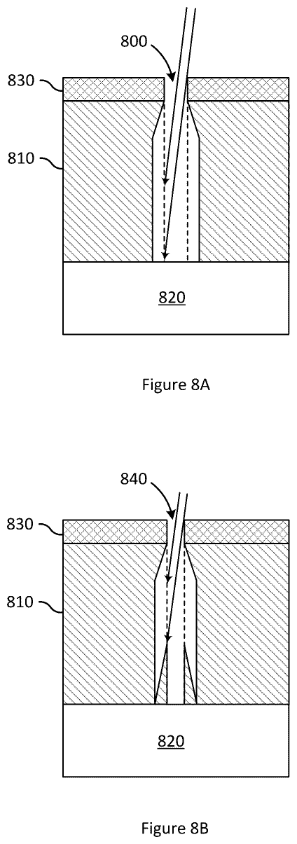

FIGS. 8A and 8B illustrate cross-sectional views of mask undercut processes for different aspect ratio features. A protective layer 830, which may comprise materials such as silicon oxide or silicon nitride, may be disposed over a mask layer 810 on a substrate 820. The protective layer 830 may preserve the integrity of the mask layer 810 during processing. The mask layer 810 and the substrate 820 may comprise the materials and structures of the mask layer 110 and the substrate 120 as described in FIGS. 1A-1B. The arrows in both figures represent the processing beam used to etch the mask layer 810.

FIG. 8A may show processing of a high aspect ratio feature 800 (e.g., an aspect ratio of approximately 5:1). In various embodiments, a low-angle processing beam (e.g., an angle of etch at approximately 11°) may be directed at the feature 800 to enable controlled undercutting of the mask layer 810. The low incident angle may allow the processing beam to reach the bottom of the feature while minimizing mask height reduction.

FIG. 8B may illustrate processing of a feature 840 with an even higher aspect ratio (e.g., an aspect ratio of approximately 10:1). Despite the increased aspect ratio, a low-angle processing beam (e.g., an angle of etch at approximately 11°) may still enable effective undercutting while preserving the mask layer height. The protective layer 830 may remain intact during processing, maintaining the structural integrity of the mask stack.

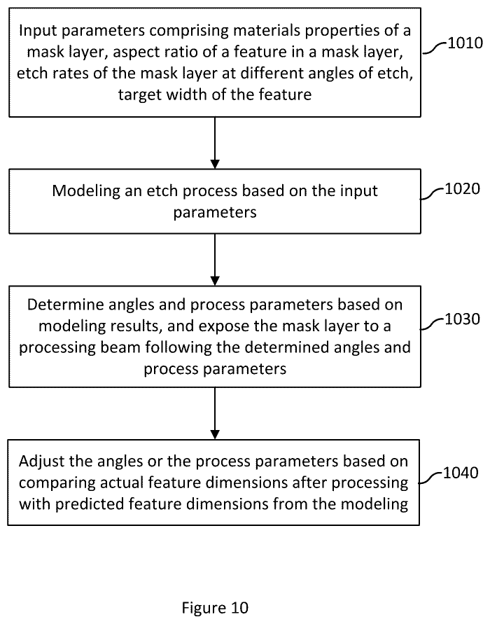

As will be discussed in more detail in FIG. 10 below, the feature aspect ratio and the corresponding angle of etch may be simulated prior to practical etch processing, enabling optimization of processing conditions for different feature geometries. The simulation capabilities may be particularly beneficial for high aspect ratio features shown in FIGS. 8A and 8B, where precise control of the undercut process is crucial. The modeling may predict optimal angles of etch (e.g., 11°) and parameters to achieve desired undercut profiles while maintaining mask integrity. This predictive approach may reduce process development time and improve manufacturing efficiency by establishing optimal processing conditions before actual implementation.

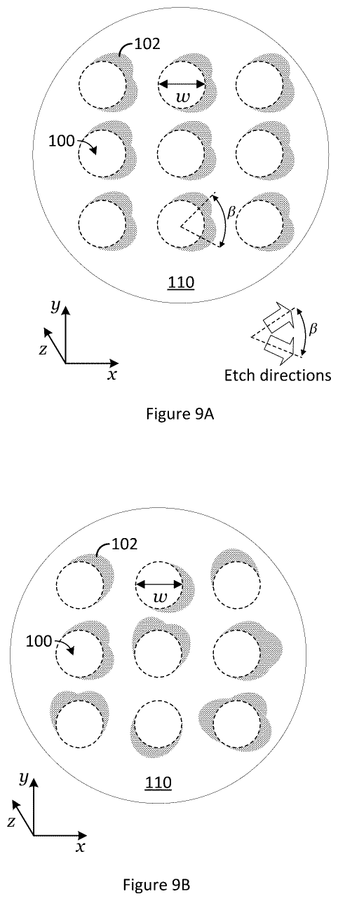

While previous figures may illustrate modification of feature width along x-axis, in certain embodiments, more complex directional processing may be employed as shown in FIGS. 9A and 9B. The processing direction may be selected based on target feature dimensions and local pattern requirements.

As shown in FIG. 9A, the feature 100 may be edited from multiple directions to achieve uniform dimensional modification. While two directions are illustrated in the figure, in various embodiments, the processing may be performed from three, four, or more directions around the feature 100 to achieve desired dimensional modifications. The shaded regions 102 around the circumference of the feature 100 may represent areas where material has been removed through multi-directional processing. In some embodiments, the processing beam may etch the mask layer 110 along one direction, and by rotating the substrate 120 by a rotation angle β, the processing beam may etch the mask layer 110 along another direction. In some embodiments, the rotation angle β may be smaller than 180°. In other embodiments, the rotation angle β may be greater than 180° and smaller than 360°.

FIG. 9B illustrates selective directional processing where different features 100 on the same substrate 120 may be modified using different processing directions. In some embodiments, one feature 100 may be edited along one direction, while another feature 100 may be edited along a different direction. In some embodiments, one feature 100 may be edited along a single direction, while another feature 100 may be edited along multiple directions. In various embodiments, the substrate 120 may be rotated by different rotation angles β between editing different features 100. The width w of individual features 100 may be modified independently by controlling the direction and duration of the etch process. This selective approach may provide flexibility in optimizing feature dimensions based on their location or specific dimensional requirements.

In various embodiments, the processing beam may be scanned across the substrate 120 to etch the mask layer 110 using different scanning patterns and strategies. In one embodiment, the processing beam may be scanned across the whole substrate 120 in multiple directions, with overlapping scan paths in different orientations. This multi-directional scanning across the entire substrate may provide uniform processing coverage. In another embodiment, different regions of the substrate 120 may be processed using separate scanning patterns, where each region may have its own scan direction and pattern optimized for local feature requirements. Additionally, customized scanning patterns may be implemented, where the beam path may follow complex trajectories to accommodate specific pattern layouts or feature distributions. These varied scanning strategies may enable flexible processing schemes adapted to different feature arrangements and dimensional modification requirements across the substrate.

In various embodiments, the angles of etch such as the first, the second, the third, and the fourth angles θ₁, θ₂, θ₃, and θ₄, as well as the associated process parameters may be determined based on a modeling method before implemented in actual processing. FIG. 10 illustrates a flowchart of a method for determining angles of etch for etching a mask layer, in accordance with an embodiment.

At operation 1010, input parameters may be received for modeling an etch process. The input parameters may comprise materials properties of the mask layer, an aspect ratio of a feature in the mask layer, etch rates of the mask layer at different angles of etch, a target width of the feature, and processing beam characteristics. In some embodiments, the input parameters may further comprise process parameters as described with reference to FIG. 1A.

At operation 1020, the method may include modeling the etch process based on the input parameters at operation 1010. In various embodiments, the modeling may comprise simulating profiles of etch at different angles of etch and process parameters, calculating rates of material removal from the mask layer, and predicting changes of the aspect ratio during processing. In some embodiments, the modeling may account for increasing the angles of etch to accommodate reduced aspect ratio of the feature as processing progresses. In various embodiments, the modeling may evaluate various angles of etch and process parameters to optimize feature dimension modification while minimizing mask layer height reduction. In some embodiments, the modeling may select angles of etch based on Equation 1. The modeling may reduce or eliminate the need for multiple experimental wafer runs, decreasing material waste and equipment time usage.

At operation 1030, the angles of etch and the process parameters leading to targeted width of the feature may be determined based on the modeling results. In some embodiments, a first angle between the processing beam and a normal direction of the substrate may be determined based on the initial aspect ratio of the feature. The substrate may be exposed to the processing beam at the first angle using a first set of process parameters. The exposure to the processing beam may reduce the aspect ratio of the feature. In some embodiments, a second angle may be determined based on the reduced aspect ratio, where the second angle may be larger than the first angle to accommodate the reduced aspect ratio. The substrate may be exposed to the processing beam at the second angle using a second set of process parameters. The exposure to the processing beam may further reduce the aspect ratio of the feature. In various embodiments, additional angles of etch may be determined based on the further reduced aspect ratio. For example, a third angle, which may be larger than the second angle, may be determined to accommodate further reductions in aspect ratio during processing. In various embodiments, the substrate may be rotated by an angle about the axis normal to the major surface of the substrate between exposing to the processing beam at different angles of etch. The rotation of substrate may enable uniform etching of the substrate.

At operation 1040, in various embodiments, the method may further include adjusting the angles of etch or the process parameters based on comparing actual feature dimensions after processing with predicted feature dimensions from the modeling. In some embodiments, the angles of etch or process parameters may be adjusted if actual feature dimensions deviate from predicted dimensions. In various embodiments, the differences between the actual and the predicted feature dimensions may be used as feedback to the model to continuously improve modeling accuracy.

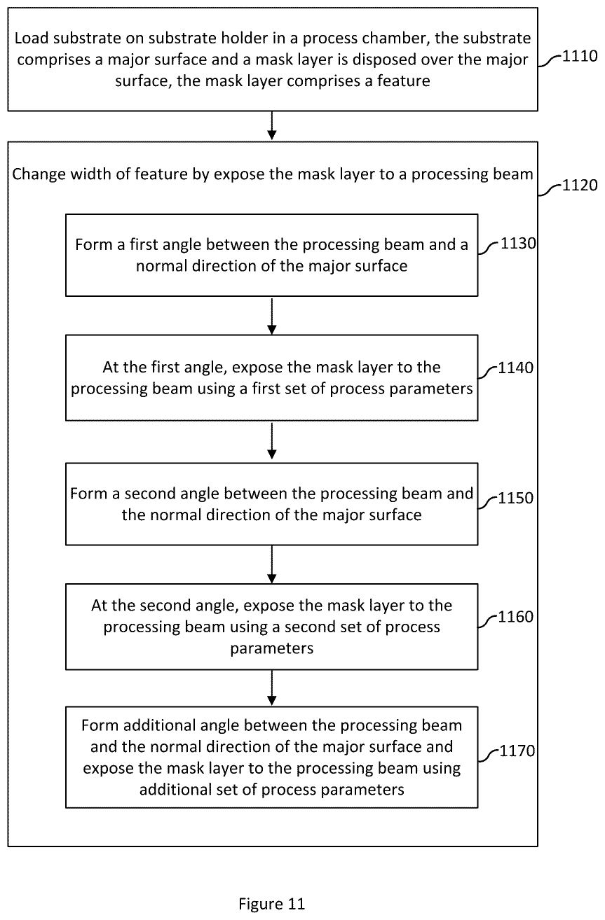

FIG. 11 illustrates a flowchart of a method for processing a substrate using a processing beam, in accordance with an embodiment.

At operation 1110, the substrate may be loaded onto a substrate holder in a processing chamber. The substrate may comprise a major surface, and a mask layer may be disposed over the major surface. The mask layer may comprise a feature requiring dimensional modification, for example, a width modification. The substrate, the mask layer, and the feature may comprise the materials, structures, or geometrical dimensions as described with reference to the corresponding parts in FIGS. 1A-4D.

At operation 1120, the method may include modifying a width of the feature by exposing the mask layer to the processing beam. In some embodiments, the processing beam may be the GCB as described above with reference to FIG. 1A. In some embodiments, the GCB may comprise gas clusters comprising inert gases such as nitrogen and argon, or reactants such as O₂, CO₂, NH₃, NF₃, SF₆, CF₄, CHF₃, or the like, or a mixture of several gases. The size of gas clusters may range from hundreds to thousands of atoms or molecules per cluster. In alternative embodiments, the processing beam may be an ion beam, an ion sheet, a plasma torch, a neutral beam stream, a particle beam, or a directional radiation from a laser.

At operation 1130, a first angle may be formed between the processing beam and a normal direction of the major surface. When the aspect ratio is higher at the beginning of processing, the first angle may be selected to ensure the processing beam reaches the bottom of features while minimizing mask layer height reduction. In some embodiments, the first angle may be selected based on the aspect ratio of the feature as calculated in Equation 1.

At operation 1140, the mask layer may be exposed to the processing beam at the first angle using a first set of process parameters. In some embodiments, the set of process parameters may comprise the components as described above about process parameters with reference to FIG. 1A. In some embodiments, the exposure may result in a height reduction and a width modification as illustrated in FIG. 2A, 3A or 4A.

At operation 1150, a second angle may be formed between the processing beam and the normal direction of the major surface. In some embodiments, the second angle may be larger than the first angle to compensate for the reduced aspect ratio resulting from previous processing steps. In some embodiments, the second angle may be selected based on the method of selecting the second angle described above with reference to FIG. 2C.

At operation 1160, the mask layer may be exposed to the processing beam at the second angle using a second set of process parameters, leading to additional height reduction and width modification. In some embodiments, the second set of process parameters may be different from the first set of process parameters.

At operation 1170, additional angles may be formed between the processing beam and the normal direction of the major surface as needed. Similar to the processing sequences shown in FIGS. 2A-2D, 3A-3D, and 4A-4D, these additional processing steps may include rotating the substrate about an axis normal to the major surface or processing at different angles of etch. As illustrated in FIGS. 2A-4D, each processing step may remove material from the mask layer, indicated by dotted regions, until target feature dimensions are achieved.

In various embodiments, the sequence of operations shown in FIG. 11 may provide a systematic approach to modifying feature dimensions using the processing beam. The method may incorporate various processing sequences and steps illustrated in FIGS. 2A-4D, including angle adjustment based on aspect ratio changes, substrate rotation for uniform processing, and multiple processing steps with different process parameters to achieve desired feature width modifications while suppressing mask layer height reduction.

While previous figures illustrate dimensional modification of the features 100 in the mask layer 110, in various embodiments, similar processing methods may be applied to modify features in other types of layers. These processing methods may be particularly beneficial in cases where the mask layer may be removed faster than the underlying substrate, resulting in decreasing aspect ratios during etch processing. These layers may include, but are not limited to, dielectric layers such as silicon oxide, silicon nitride, or low-k dielectric materials; semiconductor layers such as silicon, germanium, or compound semiconductors; conductive layers such as metal layers, metal silicide, or polysilicon; or various combinations of these materials. The processing beam may be used to expand feature dimensions in these different material layers by adjusting process parameters based on specific material properties and dimensional requirements. For example, the angles of etch and process parameters may be optimized for modifying contact holes in dielectric layers, expanding trenches in semiconductor layers, or adjusting critical dimensions in metal interconnect layers. The methods described for mask layer modification may be adapted for these different materials by selecting appropriate beam characteristics, processing angles, and process parameters suitable for each material system.

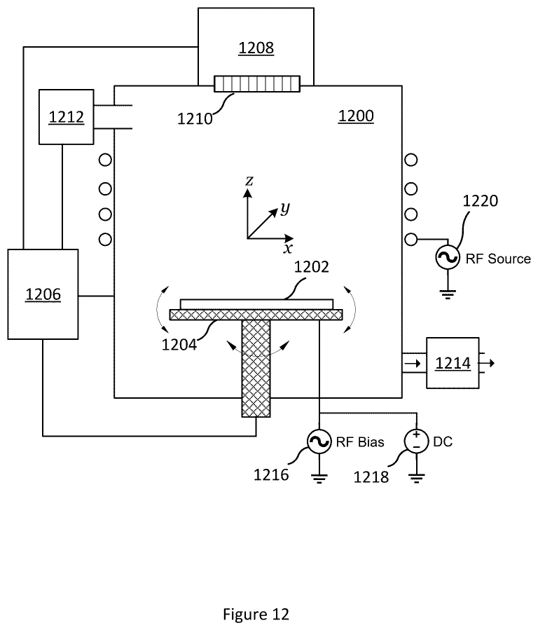

FIG. 12 illustrates a schematic diagram of a processing system for modifying a substrate using a processing beam, in accordance with an embodiment. The processing chamber 1200 may be configured to maintain a controlled processing environment including temperature or pressure. In various embodiments, a substrate holder 1204 may be disposed within the processing chamber 1200 and configured to support a substrate 1202. In various embodiments, a mask layer may be disposed over the substrate 1202, wherein the mask layer may comprise a feature requiring dimensional modification. In various embodiments, the feature may include vias, trenches, lines, or other structures formed in photoresist or hard mask materials.

In some embodiments, the substrate holder 1204 may be configured to move in multiple degrees of freedom with respect to the coordinate system (x, y, z). In one or more embodiments, the substrate holder 1204 may tilt around the x-axis and γ-axis to form various angles with respect to the z-axis, and may rotate around the z-axis or move within the x-y plane to enable processing of different regions of the substrate 1202. Though not explicitly illustrated in FIG. 12, the movements of the substrate holder 1204 may be implemented using various mechanical components such as gears, motors, and actuators controlled by signals from a controller 1206.

In various embodiments, a processing beam source 1208 may comprise different types of beam generators to supply processing beams for etching the substrate 1202. In some embodiments, the processing beam source 1208 may be a gas cluster beam source configured to generate clusters of gas atoms or molecules of various sizes, loosely bound by van der Waals forces. In various embodiments, the processing beam source 1208 may generate gas clusters by expanding gas through a processing nozzle 1210 under specific pressure and temperature conditions that promote cluster formation. The spot size of a gas cluster beam may vary from a few microns to a few centimeters. And the size of gas clusters may range from hundreds to thousands of atoms or molecules per cluster. In various semiconductor processing applications, the gas cluster beam may comprise inert gases such as nitrogen and argon, or reactants such as O₂, CO₂, NH₃, NF₃, SF₆, CF₄, CHF₃, or the like, or a mixture of several gases. The gas cluster beam energy, cluster size distribution, and beam current may be controlled by adjusting source parameters. In various embodiments, the gas cluster beam may be used to remove materials from the mask layer 110 as illustrated in FIGS. 1A-4D.

In other embodiments, the processing beam source 1208 may be an ion beam source, a plasma source, a neutral beam source, or a radiation source. In some embodiments, the processing beam source 1208 may be the ion beam source which generates directional ions through plasma generation and extraction. In some embodiments, the processing beam source 1208 may be the plasma source which generates a directed stream of plasma species including ions, electrons, and radicals. In alternative embodiments, the processing beam source 1208 may comprise a neutral beam source that generates directional beams of neutral species. In yet other embodiments, the processing beam source 1208 may comprise a radiation source such as a laser or other electromagnetic radiation generator.

The configuration of the processing nozzle 1210 may vary depending on the type of processing beam source 1208. In embodiments using gas cluster beams, the processing nozzle 1210 may be configured for gas expansion and cluster formation as described above. For ion beam sources, the processing nozzle 1210 may be replaced with ion extraction and focusing optics. In embodiments using plasma sources, the processing nozzle 1210 may be specially designed plasma extraction ports or apertures instead of traditional nozzles. In embodiments using neutral beams, the processing nozzle 1210 may be configured with neutralization capabilities. For radiation sources, the processing nozzle 1210 may be replaced with appropriate beam shaping and focusing optics. The beam spot size, energy distribution, and other characteristics may be controlled through appropriate source parameters and beam delivery components specific to each type of processing beam.

In some embodiments, the gas source 1212 may supply process gases to the processing chamber 1200. A vacuum pump 1214 may be coupled to the processing chamber 1200 to control the chamber pressure and remove process byproducts. In various embodiments, RF power may be supplied by RF source 1220 for plasma generation within the processing chamber 1200. In some embodiments, RF bias power from RF bias source 1216 and DC bias power from DC source 1218 may be applied to the substrate holder 1204 to control the energy and direction of ion bombardment onto the substrate 1202.

A controller 1206 may be coupled to various components of the processing system to control their operations. In various embodiments, the controller 1206 may include a processor configured to execute instructions stored in a memory. The memory may include random access memory (RAM), read-only memory (ROM), or other types of memory devices. The memory may store instructions that, when executed by the processor, cause the controller 1206 to perform various operations as described in previous FIGS. 1A-4D and FIG. 11. In some embodiments, the instructions may include: controlling the movement, tilt, and rotation of the substrate holder 1204; controlling the gas cluster beam parameters through processing beam source 1208; regulating gas flow from gas source 1212; managing chamber pressure through pump 1214; and controlling bias power sources 1216 and 1218. In some embodiments, the controller 1206 may also include interfaces for receiving input parameters and displaying process information.

In an exemplary embodiment, the instructions stored in the memory of the controller 1206 may comprise: forming a first angle between a processing beam and a normal direction of a major surface of the substrate; exposing the mask layer to the processing beam at the first angle using a first set of process parameters; forming a second angle between the processing beam and the normal direction of the major surface, where the second angle being different from the first angle; exposing the mask layer to the processing beam at the second angle using a second set of process parameters; rotating the substrate about an axis normal to the substrate; forming a third angle between the processing beam and the normal direction of the major surface; exposing the mask layer to the processing beam at the third angle using a third set of process parameters; forming a fourth angle between the processing beam and the normal direction of the major surface, where the fourth angle being different from the third angle; and exposing the mask layer to the processing beam at the fourth angle using a fourth set of process parameters.

Example embodiments of the invention are described below. Other embodiments can also be understood from the entirety of the specification as well as the claims filed herein.

Example 1. A method for processing a substrate, the method including: receiving the substrate on a substrate holder disposed in a processing chamber, the substrate including a major surface, and a mask layer disposed over the major surface, the mask layer including a feature; forming a first angle between a processing beam and a normal direction of the major surface; exposing the mask layer to the processing beam at the first angle using a first set of process parameters; forming a second angle between the processing beam and the normal direction of the major surface, the first angle being different from the second angle; and exposing the mask layer to the processing beam at the second angle using a second set of process parameters.

Example 2. The method of example 1, where the first angle is smaller than the second angle.

Example 3. The method of one of examples 1 or 2, where exposing the mask layer to the processing beam modifies a width of the feature.

Example 4. The method of one of examples 1 to 3, where the processing beam is a gas cluster beam including gas clusters.

Example 5. The method of one of examples 1 to 4, where the gas clusters include N₂, Ar, O₂, CO₂, NH₃, NF₃, SF₆, CF₄, or CHF₃.

Example 6. The method of one of examples 1 to 5, where the processing beam includes a particle beam.

Example 7. The method of one of examples 1 to 6, where the processing beam includes an ion sheet, or a plasma torch.

Example 8. The method of one of examples 1 to 7, where the mask layer includes photoresist or hard mask.

Example 9. The method of one of examples 1 to 8, where each of the first and the second sets of process parameters include: an intensity of the processing beam; a duration of exposing the mask layer to the processing beam; or a composition of the processing beam.

Example 10. The method of one of examples 1 to 9, where the first set of process parameters is different from the second set of process parameters.

Example 11. The method of one of examples 1 to 10, further including: rotating the substrate about an axis normal to the major surface; forming a third angle between the processing beam and the normal direction of the major surface; exposing the mask layer to the processing beam at the third angle using a third set of process parameters; forming a fourth angle between the processing beam and the normal direction of the major surface, the fourth angle being different from the third angle; and exposing the mask layer to the processing beam at the fourth angle using a fourth set of process parameters.

Example 12. The method of one of examples 1 to 11, where the third angle is smaller than the fourth angle.

Example 13. A method for processing a substrate, the method including: providing a substrate including a major surface and a mask layer disposed over the major surface; forming a first angle between a processing beam and a normal direction of the major surface; exposing the mask layer to the processing beam at the first angle using a first set of process parameters; rotating the substrate about an axis normal to the major surface; forming a second angle between the processing beam and the normal direction of the major surface; and exposing the mask layer to the processing beam at the second angle using a second set of process parameters.

Example 14. The method of example 13, where the processing beam is a gas cluster beam including gas clusters.

Example 15. The method of one of examples 13 or 14, further including: rotating the substrate about the axis normal to the major surface; forming a third angle between the processing beam and the normal direction of the major surface; exposing the mask layer to the processing beam at the third angle using a third set of process parameters; rotating the substrate about the axis normal to the major surface; forming a fourth angle between the processing beam and the normal direction of the major surface; and exposing the mask layer to the processing beam at the fourth angle using a fourth set of process parameters.

Example 16. The method of one of examples 13 to 15, where each of the first, the second, the third, and the fourth sets of process parameters include: an intensity of the processing beam; a duration of exposing the mask layer to the processing beam; or a composition of the processing beam.

Example 17. A system for processing a substrate, the system including: a substrate holder disposed in a process chamber and configured to hold the substrate, the substrate including a major surface, and a mask layer disposed over the major surface, the mask layer including a feature; a processing beam source configured to emit a processing beam onto the substrate through a processing nozzle; and a controller coupled to the processing beam source, the substrate holder, and a memory storing instructions to be executed in the controller, where the instructions when executed cause the controller to: form a first angle between the processing beam and a normal direction of the major surface; expose the mask layer to the processing beam at the first angle using a first set of process parameters; form a second angle between the processing beam and the normal direction of the major surface, the second angle being different from the first angle; and expose the mask layer to the processing beam at the second angle using a second set of process parameters.

Example 18. The system of example 17, where each of the first and the second sets of process parameters includes: an intensity of the processing beam; a duration of exposing the mask layer to the processing beam; or a composition of the processing beam.

Example 19. The system of one of examples 17 or 18, where the first set of process parameters is different from the second set of process parameters.

Example 20. The system of one of examples 17 to 19, where the instructions when executed further cause the controller to: rotate the substrate about an axis normal to the substrate; form a third angle between the processing beam and the normal direction of the major surface; expose the mask layer to the processing beam at the third angle using a third set of process parameters; form a fourth angle between the processing beam and the normal direction of the major surface, the fourth angle being different from the third angle; and expose the mask layer to the processing beam at the fourth angle using a fourth set of process parameters.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-12 may be combined in further embodiments. It is therefore intended that the appended claims encompass any such modifications or embodiments.

What is claimed is:

1. A method for processing a substrate, the method comprising:
receiving the substrate on a substrate holder disposed in a processing chamber, the substrate comprising a major surface, and a mask layer disposed over the major surface, the mask layer comprising a feature;
forming a first angle between a processing beam and a normal direction of the major surface;
exposing the mask layer to the processing beam at the first angle using a first set of process parameters;
forming a second angle between the processing beam and the normal direction of the major surface, the first angle being different from the second angle; and
exposing the mask layer to the processing beam at the second angle using a second set of process parameters.

2. The method of claim 1, wherein the first angle is smaller than the second angle.

3. The method of claim 1, wherein exposing the mask layer to the processing beam modifies a width of the feature.

4. The method of claim 1, wherein the processing beam is a gas cluster beam comprising gas clusters.

5. The method of claim 4, wherein the gas clusters comprise N₂, Ar, O₂, CO₂, NH₃, NF₃, SF₆, CF₄, or CHF₃.

6. The method of claim 1, wherein the processing beam comprises a particle beam.

7. The method of claim 1, wherein the processing beam comprises an ion sheet, or a plasma torch.

8. The method of claim 1, wherein the mask layer comprises photoresist or hard mask.

9. The method of claim 1, wherein each of the first and the second sets of process parameters comprise:
an intensity of the processing beam;
a duration of exposing the mask layer to the processing beam; or
a composition of the processing beam.

10. The method of claim 9, wherein the first set of process parameters is different from the second set of process parameters.

11. The method of claim 1, further comprising:
rotating the substrate about an axis normal to the major surface;
forming a third angle between the processing beam and the normal direction of the major surface;
exposing the mask layer to the processing beam at the third angle using a third set of process parameters;
forming a fourth angle between the processing beam and the normal direction of the major surface, the fourth angle being different from the third angle; and
exposing the mask layer to the processing beam at the fourth angle using a fourth set of process parameters.

12. The method of claim 11, wherein the third angle is smaller than the fourth angle.

13. A method for processing a substrate, the method comprising:
providing a substrate comprising a major surface and a mask layer disposed over the major surface;
forming a first angle between a processing beam and a normal direction of the major surface;
exposing the mask layer to the processing beam at the first angle using a first set of process parameters;
rotating the substrate about an axis normal to the major surface;
forming a second angle between the processing beam and the normal direction of the major surface; and
exposing the mask layer to the processing beam at the second angle using a second set of process parameters.

14. The method of claim 13, wherein the processing beam is a gas cluster beam comprising gas clusters.

15. The method of claim 13, further comprising:
rotating the substrate about the axis normal to the major surface;
forming a third angle between the processing beam and the normal direction of the major surface;
exposing the mask layer to the processing beam at the third angle using a third set of process parameters;
rotating the substrate about the axis normal to the major surface;
forming a fourth angle between the processing beam and the normal direction of the major surface; and
exposing the mask layer to the processing beam at the fourth angle using a fourth set of process parameters.

16. The method of claim 15, wherein each of the first, the second, the third, and the fourth sets of process parameters comprise:
an intensity of the processing beam;
a duration of exposing the mask layer to the processing beam; or
a composition of the processing beam.

17. A system for processing a substrate, the system comprising:
a substrate holder disposed in a process chamber and configured to hold the substrate, the substrate comprising a major surface, and a mask layer disposed over the major surface, the mask layer comprising a feature;
a processing beam source configured to emit a processing beam onto the substrate through a processing nozzle; and
a controller coupled to the processing beam source, the substrate holder, and a memory storing instructions to be executed in the controller, wherein the instructions when executed cause the controller to:
form a first angle between the processing beam and a normal direction of the major surface;
expose the mask layer to the processing beam at the first angle using a first set of process parameters;
form a second angle between the processing beam and the normal direction of the major surface, the second angle being different from the first angle; and
expose the mask layer to the processing beam at the second angle using a second set of process parameters.

18. The system of claim 17, wherein each of the first and the second sets of process parameters comprises:
an intensity of the processing beam;
a duration of exposing the mask layer to the processing beam; or
a composition of the processing beam.

19. The system of claim 17, wherein the first set of process parameters is different from the second set of process parameters.

20. The system of claim 17, wherein the instructions when executed further cause the controller to:
rotate the substrate about an axis normal to the substrate;
form a third angle between the processing beam and the normal direction of the major surface;
expose the mask layer to the processing beam at the third angle using a third set of process parameters;
form a fourth angle between the processing beam and the normal direction of the major surface, the fourth angle being different from the third angle; and
expose the mask layer to the processing beam at the fourth angle using a fourth set of process parameters.
